(19) United States
(12) Patent Application Publication
(10) Pub. No.: US 2020/0232090 A1
(43) Pub. Date: Jul. 23, 2020

(54) SUBSTRATE PROCESSING DEVICE AND PROCESSING SYSTEM

(71) Applicant: TOKYO ELECTRON LIMITED, Tokyo (JP)

(72) Inventors: Hiroki MAEHARA, Yamanashi (JP); Naoki WATANABE, Yamanashi (JP); Toru ISHII, Iwate (JP); Kanto NAKAMURA, Yamanashi (JP); Makoto SAITO, Dublin (IE); David HURLEY, Dublin (IE); Ian COLGAN, Dublin (IE)

(21) Appl. No.: 16/488,217

(22) PCT Filed: Feb. 21, 2018
(86) PCT No.: PCT/JP2018/006163

§ 371 Date: Aug. 22, 2019

(30) Foreign Application Priority Data
Feb. 23, 2017 (JP) 2017-032255

(51) Int. Cl. C23C 14/54; H01L 21/683; H01L 21/67; H01L 21/677; H01L 43/12; C23C 14/56; C23C 14/50; C23C 14/52

(52) U.S. Cl. CPC C23C 14/541; H01L 21/683; H01L 21/67103; H01L 21/67742; H01L 21/67167; C23C 14/52; H01L 43/12; H01L 21/67196; C23C 14/566; C23C 14/50; H01L 21/67253

(57) ABSTRACT

A substrate processing device and a processing system process substrates each having a magnetic layer individually and are provided with: a support unit for supporting a substrate; a heating unit for heating the substrate supported on the support unit; a cooling unit for cooling the substrate supported on the support unit; a magnet unit for generating a magnetic field; and a processing chamber accommodating the support unit, the heating unit, and the cooling unit. The magnet unit includes a first and a second end surface which extend in parallel. The first and the second end surface are opposite to each other while being spaced apart from each other. The first end surface corresponds to a first magnetic pole of the magnet unit. The second end surface corresponds to a second magnetic pole of the magnet unit. The processing chamber is disposed between the first and the second end surface.

### TECHNICAL FIELD

The present invention relates to a substrate processing device and a processing system.

### BACKGROUND

In manufacturing a magnetization random access memory (MRAM), a magnetization process and an annealing process are performed on a magnetic tunnel junction (MTJ) element formed by a single wafer physical vapor deposition (PVD) film forming apparatus. Patent Document 1 discloses a technique related to a vacuum heating and cooling apparatus for rapidly heating and cooling only a substrate while maintaining a high vacuum state after a film forming process. In addition, Patent Document 2 discloses a technique related to a magnetic annealing apparatus for suppressing adhesion of impurities onto a semiconductor wafer.

### Prior Art

Patent Document 1: International Application Publication No. 2010/150590

Patent Document 2: Japanese Patent Application Publication No. 2014-181880

In the MRAM manufacturing process, plural MTJ elements are sequentially taken out from the single wafer PVD film forming apparatus after the film forming process and collectively transferred to an apparatus different from the PVD film forming apparatus to be subjected to the magnetization process and the annealing process. After the magnetization process and the annealing process are collectively performed on the MTJ elements, characteristics (a magnetoresistance ratio and the like) of the MTJ elements are individually evaluated using a current-in-plane tunneling (CIPT) measuring device or the like. In this case, if the characteristic evaluation result shows a possibility of defects in the manufacturing process, the entire MTJ elements are considered to be manufactured by the manufacturing process in which the defects have occurred since the characteristic evaluation is performed after the plural MTJ elements are collectively subjected to the magnetization process and the annealing process. Accordingly, there is a demand for a substrate processing device and a processing system capable of performing on substrates one by one a magnetization process and an annealing process after the film forming process in the MRAM manufacturing process.

### SUMMARY

In accordance with a first aspect, there is provided a substrate processing device for processing substrates one by one, each having a magnetic layer, the substrate processing device including: a support unit configured to supporting a substrate; a heating unit configured to heat the substrate supported by the support unit; a cooling unit configured to cool the substrate supported by the support unit; a processing chamber configured to accommodate the support unit, the heating unit, and the cooling unit; and a magnet unit configured to generate a magnetic field. The magnet unit has a first end surface and a second end surface extending in parallel to each other. The first end surface and the second end surface are opposite to each other while being spaced apart from each other. The first end surface corresponds to a first magnetic pole of the magnet unit, and the second end surface corresponds to a second magnetic pole of the magnet unit. The processing chamber is disposed between the first end surface and the second end surface.

With such configuration, the magnet unit, the support unit for mounting the substrate, the heating unit and the cooling unit, which are required to perform the magnetization process and the annealing process on the substrate having the magnetic layer, are all included in the single substrate processing device that processes the substrates one by one. Therefore, the magnetization process and the annealing process can be performed on the substrates one by one. Accordingly, in the first aspect, the magnetization process and the annealing process can be performed on the substrates one by one after the film forming process in the MRAM manufacturing process.

Further, in the first aspect, in a state where the substrate is supported by the support unit, the substrate may be disposed to be covered by the first end surface when viewed from the first end surface and by the second end surface when viewed from the second end surface while the substrate extends in parallel with the first end surface and the second end surface. Therefore, magnetic force lines generated between the first end surface and the second end surface may be perpendicular to the extending direction of the substrate supported by the support unit (perpendicular to the surface of the substrate).

Further, in the first aspect, in a state where the substrate is supported by the support unit in the processing chamber, the cooling unit may be disposed between a position of the substrate in the processing chamber and the first end surface, and the heating unit may be disposed between the position of the substrate and the cooling unit. In this configuration, the substrate supported by the support unit is disposed between the heating unit and the cooling unit. Therefore, the substrate can be effectively heated and cooled.

Further, in the first aspect, the substrate processing device described above may further include a moving mechanism configured to move the substrate. In the state where the substrate is supported by the support unit, the moving mechanism may move the substrate toward or away from the cooling unit while maintaining the substrate in parallel with the first end surface and the second end surface. Therefore, in the case of cooling the substrate, the substrate can be moved closer to the cooling unit, so that the substrate can be more effectively cooled.

Further, in the first aspect, in a state where the substrate is supported by the support unit in the processing chamber, the cooling unit may be disposed between a position (arrangement position) of the substrate in the processing chamber and the first end surface, and the heating unit may be disposed between the position of the substrate and the cooling unit. With such configuration, the heating and the cooling are performed on the same surface of the substrate. Therefore, in the case of sequentially heating and cooling the substrate, the heated substrate can be more effectively cooled.

Further, in the first aspect, the heating unit may include a first heating layer and a second heating layer, and the cooling unit may include a first cooling layer and a second cooling layer. In a state where the substrate is supported by the support unit in the processing chamber, the first cooling layer may be disposed between a position (arrangement position) of the substrate in the processing chamber and the first end surface, the second cooling layer may be disposed between the position of the substrate in the processing chamber and the second end surface, the first heating layer may be disposed between the position of the substrate and the first cooling layer, and the second heating layer may be disposed between the position of the substrate and the second cooling layer. With such configuration, the heating and the cooling are performed on each of two different surfaces of the substrate. Therefore, the substrate can be sufficiently heated and cooled within a shorter period of time. Further, in the case of sequentially heating and cooling the substrate, the heated substrate can be more effectively cooled.

In accordance with a second aspect, there is provided a processing system including: a plurality of film forming apparatuses; the substrate processing device described above; and a measuring device. The film forming apparatuses are configured to form magnetic layers on substrates, respectively. The substrate processing device is configured to process the substrates having the magnetic layers formed by the film forming apparatuses one by one. The measuring device is configured to measure electromagnetic characteristic values of the substrates having the magnetic layers formed by the film forming apparatuses and the substrates processed by the substrate processing device one by one. With such configuration, the magnet unit, the support unit for mounting the substrate, the heating unit and the cooling unit, which are required to perform the magnetization process and the annealing process on the substrate having the magnetic layer, are all included in the single substrate processing device that processes the substrates one by one. Therefore, the magnetization process and the annealing process can be performed on the substrates one by one and, further, the electromagnetic characteristic values of the substrates having the magnetic layers formed by the film forming apparatuses and the substrates processed by the substrate processing device one by one.

Further, in the second aspect, the processing system may further include an atmospheric transfer chamber, and the measuring device may be connected to the atmospheric transfer chamber. With such configuration, since the measuring device can be installed through the atmospheric transfer chamber of the processing system, restrictions on the installation location of the measuring device can be reduced and, thus, the installation of the measuring device can be easily performed.

Further, in the second aspect, each of the electromagnetic characteristic values may be a magnetoresistance ratio. With such configuration, by measuring the magnetoresistance ratio of the substrate, the electromagnetic characteristic of the substrate can be satisfactorily evaluated.

As described above, it is possible to provide the substrate processing device and the processing system capable of performing on the substrates one by one a magnetization process and an annealing process after the film forming process in the MRAM manufacturing process.

### BRIEF DESCRIPTION OF THE DRAWINGS

FIG. 1 shows an example of a main configuration of a substrate processing device according to an embodiment.

FIG. 2 shows an example of a main configuration of a processing system including the substrate processing device shown in FIG. 1.

FIGS. 3A and 3B are perspective views showing an external appearance of the substrate processing device shown in FIG. 1, particularly two types of shapes of a yoke of the substrate processing device.

FIG. 4 schematically shows one aspect of a heating unit and a cooling unit arranged in a processing chamber shown in FIG. 1.

FIG. 5 schematically shows another aspect of the heating unit and the cooling unit arranged in the processing chamber shown in FIG. 1.

FIG. 6 schematically shows still another aspect of the heating unit and the cooling unit arranged in the processing chamber shown in FIG. 1.

FIG. 7 is a flowchart of a process of the processing system shown in FIG. 2.

### DETAILED DESCRIPTION

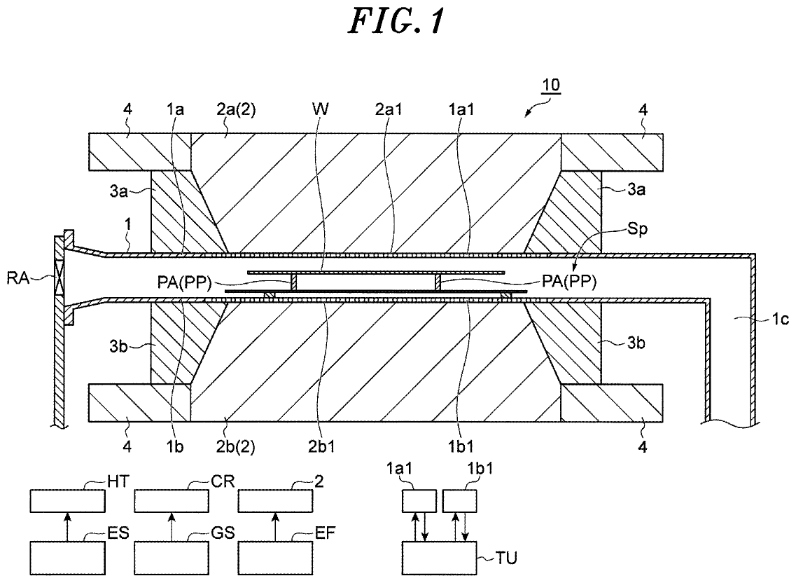

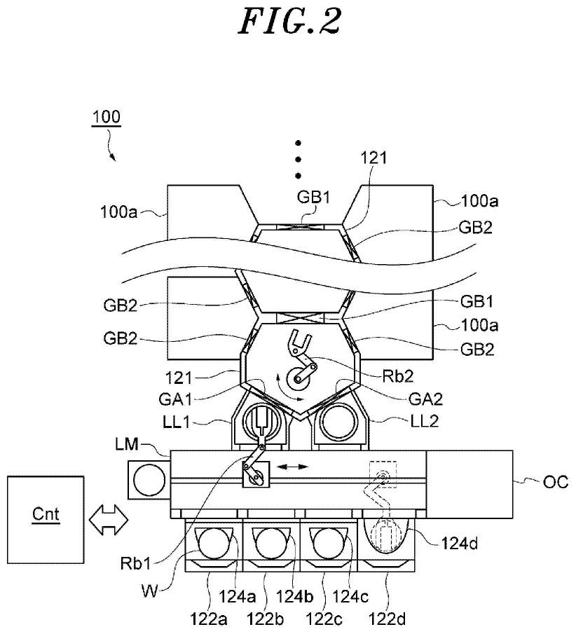

Hereinafter, various embodiments will be described in detail with reference to the drawings. Like reference numerals will be used for like parts throughout the drawings. FIG. 1 shows an example of a main configuration of a substrate processing device 10 according to an embodiment. The substrate processing device 10 is used for manufacturing an MRAM, and performs a magnetization process and an annealing process after an MTJ element (e.g., an element having an MgO/CoFeB laminated film) is formed on a substrate (hereinafter, may be referred to as “wafer W”) having a magnetic layer. The substrate processing device 10 may be installed in a processing system 100 shown in FIG. 2 to be described later.

The substrate processing device 10 includes a substrate processing device 10, a magnet unit 2, a power supply EF, wire portions 3a and 3b, a yoke 4, a cooling unit CR, a heating unit HT, a power supply ES, a gas supply unit GS, a gate valve RA, a chiller unit TU, and a support unit PP (including three or more support pins PA, the same hereinafter). A processing chamber 1 defines a processing space Sp where the wafer W (substrate) is processed. The processing chamber 1 includes a first wall 1a, a second wall 1b, and a gas exhaust line 1c. The support unit PP, the heating unit HT, and the cooling unit CR are accommodated in the processing chamber 1.

The first wall 1a includes a first heat insulating layer 1a1. The second wall 1b includes a second heat insulating layer 1bl. The magnet unit 2 includes a first core portion 2a and a second core portion 2b. The first core portion 2a has a first end surface 2a1. The second core portion 2b has a second end surface 2b1.

In the processing chamber 1, the wafer W is supported by the support unit PP. The wafer W is transferred from a transfer chamber 121 into the processing space Sp of the processing chamber 1 through a gate valve RA by a transfer robot Rb2 shown in FIG. 2. Then, the wafer W is supported by the support unit PP. In a state where the wafer W is supported by the support unit PP in the processing space Sp, the wafer W is disposed between (covered by) the first end surface 2a1 of the first core portion 2a of the magnet unit 2 and the second end surface 2b1 of the second core portion 2b of the magnet unit 2 when viewed from the first end surface 2a1 and the second end surface 2ba, and extends in parallel to the first end surface 2a1 and the second end surface 2b1. When the substrate processing device 10 is installed in the processing system 100, the wafer W extends in a direction perpendicular to a vertical direction while being supported by the support unit PP in the processing space Sp.

The magnet unit 2 is an electromagnet and generates a magnetic field by a current supplied from the power supply EF to the wire portions 3a and 3b. The wire portion 3a is a copper wire or the like wound around the first core portion 2a, and the wire portion 3b is a copper wire wound around the second core portion 2b. The first end surface 2a1 corresponds to a first magnetic pole of the magnet unit 2, and the second end surface 2b1 corresponds to a second magnetic pole of the magnet unit 2. The first magnetic pole and the second magnetic pole may be, e.g., an N pole and an S pole, respectively. The first end surface 2a1 and the second end surface 2b1 extend in parallel to each other and are opposite to each other while being spaced apart from each other. The wire portion 3a is disposed to surround the first core portion 2a, and the wire portion 3b is disposed to surround the second core portion 2b. The first core portion 2a and the second core portion 2b are made of metal, e.g., iron or the like, and cause the magnetic force lines generated by the wire portions 3a and 3b to converge at the first end surface 2a1 and the second end surface 2b1. The processing chamber 1 is disposed between the first end surface 2a1 of the magnet unit 2 and the second end surface 2b1 of the magnet unit 2. The first core 2a (the first end surface 2a1) of the magnet unit 2 is disposed above the first wall 1a of the processing chamber 1 in a direction towards the outside the processing chamber 1. The second core portion 2b of the magnet unit 2 (the second end surface 2b1) is disposed above the second wall 1b of the processing chamber 1 in a direction towards the outside the processing chamber 1. The first wall 1a may be in contact with the first end surface 2a1. The second wall 1b may be in contact with the second end surface 2b1.

The first heat insulating layer 1a1 is disposed in the first wall 1a. The first heat insulating layer 1a1 is, e.g., a water cooling jacket disposed in the first wall 1a. The first heat insulating layer 1a1 may be in contact with the first end surface 2a1. The second heat insulating layer 1b1 is disposed in the second wall 1b. The second heat insulating layer 1b1 is, e.g., a water cooling jacket disposed in the second wall 1b. The second heat insulating layer 1b1 may be in contact with the second end surface 2b1. The water cooling jacket of the first heat insulating layer 1a1 and the water cooling jacket of the second heat insulating layer 1b1 have lines connected to the chiller unit TU. The chiller unit TU suppresses heat transfer (insulates heat) between the processing chamber 1 and the magnet unit 2 by circulating a coolant through the lines (the first heat insulating layer 1a1 and the second heat insulating layer 1b1). The first heat insulating layer 1a1 and the second heat insulating layer 1b1 may be made of, e.g., a fiber-based or a foam-based heat insulating material. In this case, the heat insulating material may be disposed between the first wall 1a and the first end surface 2a1 of the first core portion 2a and between the second wall 1b and the second end surface 2b1 of the second core portion 2b.

When the substrate processing device 10 is installed in the processing system 100, the first end surface 2a1 and the second end surface 2b1 extend in a direction perpendicular to the vertical direction, and the first end surface 2a1 is positioned above the second end surface 2b1 in the vertical direction.

When viewed from the wafer W supported by the support unit PP in the processing space Sp, the wafer W is disposed between (covered by) the first end surface 2a1 and the second end surface 2b1. In other words, when viewed from the first core portion 2a of the magnet unit 2, the wafer W is disposed to be covered by the first end surface 2a1. Further, when viewed from the second core portion 2b of the magnet unit 2, the wafer W is disposed to be covered by the second end surface 2b1. Magnetic force lines generated by the magnet unit 2 are perpendicular to the wafer W supported by the support unit PP in the processing space Sp. A magnetic field of about 0.1 to 2 [T] may be generated on the wafer W by the magnet unit 2.

The heating unit HT heats the wafer W supported by the support unit PP. The heating unit HT may be, e.g., a resistance heater, an infrared heater, a lamp heater, or the like. The heating unit HT is operated by power supplied from the power supply ES. The heating unit HT is configured to cover the entire wafer W supported by the support unit PP when viewed from the first wall 1a and/or the second wall 1b, so that the entire surface of the wafer W (the upper surface and/or the backside of the wafer W) can be heated by the heating unit HT.

The cooling unit CR injects a cooling gas supplied from the gas supply device GS into the processing space Sp. The cooling unit CR has at least a portion that is provided at the first wall 1a in the processing chamber 1. The cooling gas may be a rare gas such as N2 gas or He gas. The cooling unit CR is configured to cover the entire wafer W supported by the support unit PP when viewed from the first wall 1a and/or the second wall 1b, so that the entire surface of the wafer W (the upper surface and/or the backside of the wafer W) can be cooled by the cooling unit CR. The cooling gas used to cool the wafer W is exhausted to the outside through the gas exhaust line 1c communicating with the processing space Sp. A gas exhaust pump (not shown) is disposed with the gas exhaust line 1c.

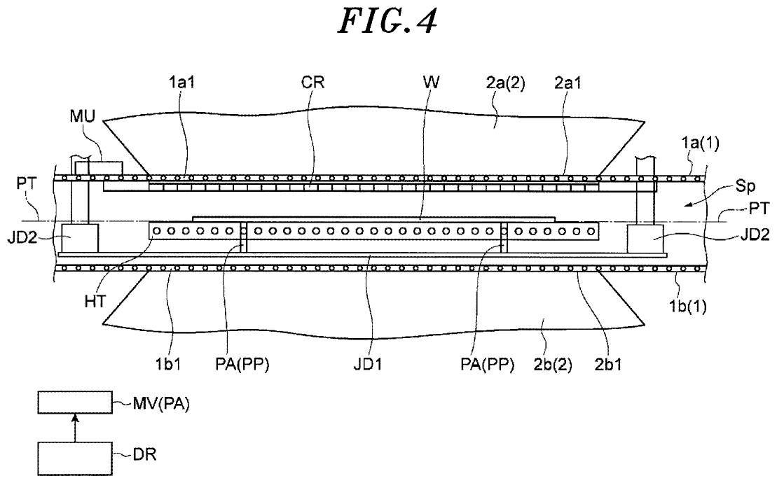

The driving of the power supply ES for supplying power to the heating unit HT, the driving of the gas supply unit GS for supplying the cooling gas to the cooling unit CR, the driving of the power supply EF for supplying power to the magnet unit 2, and the driving of the chiller unit TU for circulating a coolant through the first heat insulating layer 1a1 and the second heat insulating layer 1b1 are controlled under the control of a controller Cnt of the processing system 100 which will be described later. The controller Cnt is configured to control an opening/closing mechanism of the gate valve RA (further the driving of a power supply DR for supplying power to a moving mechanism MV in the case of the configuration shown in FIG. 4).

In accordance with the above-described substrate processing device 10, the magnet unit 2, the support unit PP, the heating unit HT, and the cooling unit CR, which are required to perform the magnetization process and the annealing process on the wafer W having the magnetic layer, are all included in the single substrate processing device 10 that processes the substrates one by one. Therefore, the magnetization process and the annealing process can be performed on wafers one by one. Accordingly, the substrate processing device 10 can perform the magnetization process and the annealing process on the wafers one by one after the film forming process in the MRAM manufacturing process. Further, in the magnet unit 2, the magnetic force lines generated between the first end surface 2a1 of the magnet unit 2 and the second end surface 2b1 of the magnet unit 2 may be perpendicular to the extending direction of the wafer W supported by the support unit PP (perpendicular to the surface of the substrate).

The processing chamber 1 shown in FIG. 1 is accommodated in any one of the processing chambers 100a of the processing system 100 shown in FIG. 2. FIG. 2 shows an example of a main configuration of the processing system 100 including the substrate processing device 10 shown in FIG. 1. In the other processing chambers 100a except the processing chamber 100a where the substrate processing device 10 is accommodated, various processes, e.g., oxidation of the metal film, metal film formation using physical vapor deposition (PVD), and the like may be performed.

The processing system 100 includes stages 122a to 122d, containers 124a to 124d, a loader module LM, a transfer robot Rb1, the controller Cnt, and a characteristic value measuring device OC, load-lock chambers LL1 and LL2, and gates GA1 and GA2. The processing system 100 further includes a plurality of transfer chambers 121, a plurality of processing chambers 100a, a plurality of gates GB1, and a plurality of gates GB2. The transfer chamber 121 includes the transfer robot Rb2.

The gate GA1 is disposed between the load-lock chamber LL1 and a portion of the transfer chamber 121 in contact with the load-lock chamber LL1. The wafer W is transferred between the load-lock chamber LL1 and the transfer chamber 121 through the gate GA1 by the transfer robot Rb2. The gate GA2 is disposed between the load-lock chamber LL2 and a portion of the transfer chamber 121 in contact with the load-lock chamber LL2. The wafer W is transferred between the load-lock chamber LL2 and the transfer chamber 121 through the gate GA2 by the transfer robot Rb2.

The gate GB1 is disposed between two adjacent transfer chambers 121. The wafer W is transferred between the two transfer chambers 121 through the gate GB1 by the transfer robot Rb2. The gate GB2 is disposed between the processing chamber 100a and a portion of the transfer chamber 121 in contact with the processing chamber 100a. The wafer W is transferred between the processing chamber 100a and the transfer chamber 121 through the gate GB2 by the transfer robot Rb2.

The stages 122a to 122d are arranged along one side of the loader module LM. The containers 124a to 124d are mounted on the stages 122a to 122d, respectively. The wafers W may be accommodated in each of the containers 124a to 124d.

The transfer robot Rb1 is disposed in the loader module LM. The transfer robot Rb1 transfers the wafer W from any one of the containers 124a to 124d and transfers the wafer W to the load-lock chamber LL1 or the load-lock chamber LL2.

The load-lock chambers LL1 and LL2 are arranged along the other side of the loader module LM and connected to the loader module LM. The load-lock chambers LL1 and LL2 constitute a preliminary decomposition chamber. The load-lock chambers LL1 and LL2 are connected to the transfer chamber 121 through the gates GA1 and GA2, respectively.

The transfer chamber 121 is a depressurization chamber. The transfer robot Rb2 is disposed in the transfer chamber 121. The substrate processing device 10 is connected to the transfer chamber 121. The transfer robot Rb2 transfers the wafer W from the load-lock chamber LL1 or LL2 to the substrate processing device 10 through the gate GA1 or GA2, respectively.

The processing system 100 further includes the characteristic value measuring device OC. The characteristic value measuring device OC may be connected to an atmosphere transfer chamber (including the loader module LM) of the processing system 100. In the embodiment shown in FIG. 2, the characteristic value measuring device OC is connected to the loader module LM. The characteristic value measuring device OC is configured to measure the electromagnetic characteristic values of the wafers W one by one, the wafers W having the magnetic layers formed by a plurality of film forming apparatuses (i.e., processing chambers 100a for performing a film forming process among the plurality of processing chambers 100a) of the processing system 100 and also measure the electromagnetic characteristic values of the wafers W, the wafers W being processed by the substrate processing device 10. The characteristic value measuring device OC may be, e.g., a current-in-plane tunneling (CIPT) measuring device capable of measuring an electromagnetic characteristic value such as a magnetoresistance ratio and the like. The wafer W can be moved and transferred between the characteristic value measuring device OC and the substrate processing device 10 by the transfer robots Rb1 and Rb2. After the wafer W is accommodated in the characteristic value measuring device OC by the transfer robot Rb1 and aligned in the characteristic value measuring device OC, the characteristic value measuring device OC measures the characteristics (e.g., the magnetoresistance ratio and the like) of the wafer W and transmits the measurement result to the controller Cnt.

The controller Cnt is a computer including a processor, a storage unit, an input device, a display device, and the like. The controller Cnt controls the respective components of the processing system 100. The controller Cnt is connected to the transport robot Rb1, the transport robot Rb2, the characteristic value measuring device OC, and various devices (e.g., the substrate processing device 10 and the like) installed in each of the processing chambers 100a. In the substrate processing device 10, the controller Cnt is connected to the power supply ES, the power supply EF (further connected to the power supply DR in the case of the configuration shown in FIG. 4), the gas supply unit GS, the chiller unit TU, the opening/closing mechanism of the gate valve RA, and the moving mechanism MV for vertically moving the support unit PP (the support pins PA), and the like. The controller Cnt operates based on a computer program (a program executed based on an inputted recipe) for controlling the respective components of the processing system 100, and transmits control signals. The respective components of the processing system 100, e.g., the transport robots Rb1 and Rb2, the characteristic value measuring device OC, and the respective components of the substrate processing device 10 are controlled by the control signals from the controller Cnt. The computer program for controlling the respective components of the processing system 100 and various data used for executing the computer program are stored in a computer-readable storage unit of the controller Cnt.

In the processing system 100 according to the above-described embodiment, it is possible to perform the film forming process, the magnetization and annealing process, and the process of measuring the characteristic value on the wafers W one by one. The film forming process is performed in two or more of the processing chambers 100a (corresponding to a plurality of film forming apparatuses). After the film forming process, the magnetization and annealing process is performed by the substrate processing device 10 disposed in any one of the processing chambers 100a. After the film forming process and the magnetization and annealing process, the process of measuring the characteristic value such as a magnetoresistance ratio of the wafer W is performed by the characteristic value measuring device OC.

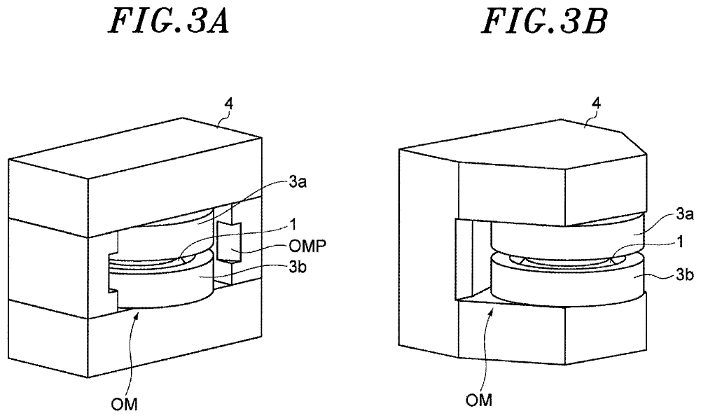

FIGS. 3A and 3B show shapes of the yoke 4 of the substrate processing device 10. In FIGS. 3A and 3B, two types of the shapes of the yoke 4 of the substrate processing device 10 shown in FIG. 1 are exemplarily illustrated.

In the case of the yoke 4 shown in FIG. 3A, an opening OM is formed at the central portion of the yoke 4 to penetrate through a side surface of the yoke 4. The processing chamber 1, the magnet unit 2, and the wire portions 3a and 3b are accommodated in the opening OM shown in FIG. 3A. The opening OM shown in FIG. 3A is disposed at a position facing the gate GB2 of the processing system 100 shown in FIG. 2. A notch OMP is formed at a portion of the opening OM shown in FIG. 3A which faces the gate GB2. Due to the provision of the opening OM and the notch OMP formed at the positions facing the gate GB2, it becomes easy to transfer the wafer W from the transfer chamber 121 of the processing system 100 into the processing chamber 1.

In the case of the yoke 4 shown in FIG. 3B, an opening OM is formed at a side surface of the yoke 4. The opening OM shown in FIG. 3B is formed as a recess on the side surface of the yoke 4. The processing chamber 1, the magnet unit 2, and the wire portions 3a and 3b are accommodated in the opening OM shown in FIG. 3B. The opening OM shown in FIG. 3B is disposed at a position facing the gate GB2 of the processing system 100 shown in FIG. 2. Due to the provision of the opening OM formed at the position facing the gate GB2 as shown in FIG. 3B, it becomes easy to transfer the wafer W from the transfer chamber 121 of the processing system 100 into the processing chamber 1.

Hereinafter, specific aspects of the heating unit HT and the cooling unit CR arranged in the processing chamber 1 will be described with reference to FIGS. 4 to 6. FIG. 4 schematically shows one aspect of the heating unit HT and the cooling unit CR arranged in the processing chamber 1. In the processing chamber 1 shown in FIG. 4, the heating unit HT, the cooling unit CR, the support unit PP, a support table JD1, a support column JD2, and the wafer W are accommodated. In the configuration shown in FIG. 4, the second wall 1b (the second heat insulating layer 1b1) is disposed above the second end surface 2b1 of the magnet unit 2; the heating unit HT is disposed above the second wall 1b; the wafer W supported by the support unit PP is disposed above the heating unit HT; the cooling unit CR is disposed above the wafer W; the first wall 1a (the first heat insulating layer 1a1) is disposed above the cooling unit CR; and the first end surface 2a1 of the magnet unit 2 is disposed above the first wall 1a. A gas supply port unit MU is disposed in the processing chamber 1 shown in FIG. 4. The support table JD1 is supported by the support column JD2, and the support pins PA are supported by the support table JD1.

The cooling unit CR shown in FIG. 4 is disposed between the first end surface 2a1 of the first core portion 2a of the magnet unit 2 and a position PT (arrangement position) of the wafer W in the processing chamber 1 in a state where the wafer W is supported by the support unit PP in the processing chamber 1. The cooling unit CR shown in FIG. 4 is disposed at the first wall 1a in the processing chamber 1. The first wall 1a is disposed above the cooling unit CR. The first end surface 2a1 of the magnet unit 2 is disposed at the first wall 1a outside the processing chamber 1. In the configuration shown in FIG. 4, the position PT is spaced apart from the cooling unit CR disposed at the first wall 1a of the processing chamber 1. The heating unit HT shown in FIG. 4 is a resistance heater. The heating unit HT is disposed between the position PT and the cooling unit CR. In the configuration shown in FIG. 4, the cooling gas supplied from the gas supply unit GS is injected from the cooling unit CR into the processing space Sp through the gas supply port unit MU.

The substrate processing device 10 having the configuration shown in FIG. 4 further includes the moving mechanism MV for moving the wafer W and the power supply DR. The moving mechanism MV is driven by power supplied from the power supply DR. The moving mechanism MV is configured to move the wafer W supported by support unit PP toward or away from the cooling unit CR disposed at the first wall 1a while maintaining the wafer W in parallel with the first end surface 2a1 of the magnet unit 2 and the second end surface 2b1 of magnet unit 2. More specifically, the moving mechanism MV vertically moves the end portion of the support unit PP (the end portions of the support pins PA which are in contact with the wafer W) between the first end surface 2a1 and the second end surface 2b1, thereby moving the wafer W supported by the support part PP between the first end surface 2a1 and the second end surface 2b1 while maintaining the wafer W in parallel with the first end surface 2a1 and the second end surface 2b1. The wafer W supported by the support unit PP is disposed at the position PT which is between the first end surface 2a1 and the second end surface 2b1 in parallel to the first end surface 2a1 and the second end surface 2b1. Further, the wafer W is movable from the position PT toward the cooling unit CR disposed on the side of the first end surface 2a1 by the moving mechanism MV.

In the configuration shown in FIG. 4, the wafer W supported by the support unit PP is disposed between the heating unit HT and the cooling unit CR disposed at the first wall 1a. Therefore, the wafer W can be effectively heated and cooled. In the case of cooling the wafer W, the wafer W can be moved closer to the cooling unit CR disposed at the first wall 1a, so that the wafer W can be more effectively cooled. In the case of loading the wafer W into the processing space Sp or unloading the wafer W from the processing space Sp by the transfer robot Rb2, the position of the wafer W can be adjusted by moving the end portion of the support unit PP to facilitate the loading and the unloading of the wafer W.

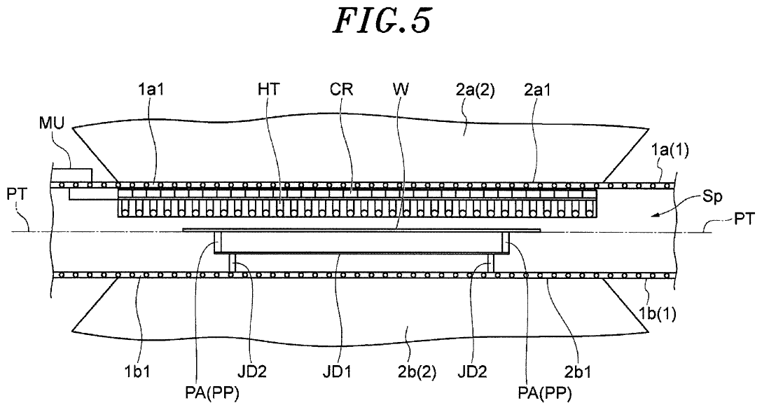

FIG. 5 schematically shows another aspect of the heating unit HT and the cooling unit CR arranged in the processing chamber 1. In the processing chamber 1 shown in FIG. 5, the heating unit HT, the cooling unit CR, the support unit PP, the support table JD1, the support column JD2, and the wafer W are accommodated. In the configuration shown in FIG. 5, the second wall 1b (the second heat insulating layer 1b1) is disposed above the second end surface 2b1 of the magnet unit 2; the wafer W supported by the support unit PP is disposed above the second wall 1b; the heating unit HT is disposed above the wafer W; the cooling unit CR is disposed above the heating unit HT; the first wall 1a (the first heat insulating layer) is disposed above the cooling unit CR; and the first end surface 2a1 of the magnet unit 2 is disposed above the first wall 1a. The gas supply port unit MU is disposed in the processing chamber 1 shown in FIG. 5. The support table JD1 is supported by the support column JD2, and the support pins PA are supported by the support table JD1.

The cooling unit CR shown in FIG. 5 is disposed between the first end surface 2a1 of the magnet unit 2 and the position PT (arrangement position) of the wafer W in the processing chamber 1 in a state where the wafer W is supported by the support unit PP in the processing chamber 1. The cooling unit CR shown in FIG. 5 is disposed at the first wall 1a. The first wall 1a is disposed above the cooling unit CR. The first end surface 2a1 of the magnet unit 2 is disposed at the first wall 1a outside the processing chamber 1. In the processing chamber 1 shown in FIG. 5, the position PT is spaced apart from the heating unit HT. The heating unit HT shown in FIG. 5 is an infrared heater or a lamp heater. The heating unit HT is disposed between the position PT and the cooling unit CR. The cooling unit CR may be in contact with the heating unit HT and the first wall 1a.

In the processing chamber 1 shown in FIG. 5, the cooling gas supplied from the gas supply device GS is injected from the cooling unit CR into the processing space Sp through the gas supply port unit MU.

In the configuration shown in FIG. 5, the heating and the cooling are performed on the same surface of the wafer W. Therefore, in the case of sequentially heating and cooling the wafer W, the heated wafer W can be more effectively cooled.

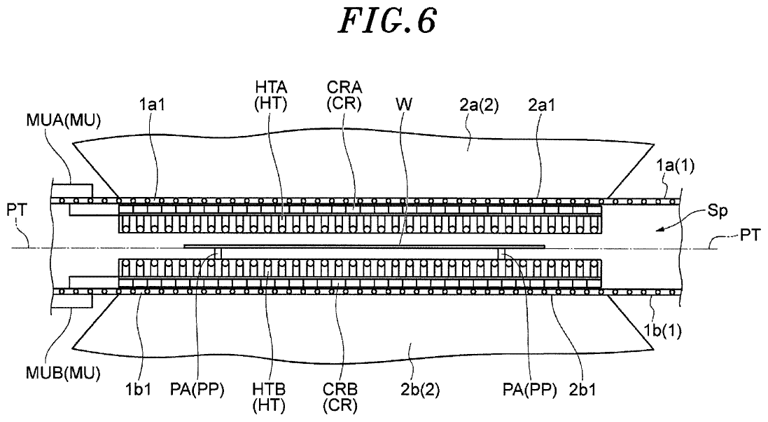

FIG. 6 schematically shows another aspect of the heating unit HT and the cooling unit CR arranged in the processing chamber 1. In the processing chamber 1 shown in FIG. 6, the heating unit HT, the cooling unit CR, the support unit PP, and the wafer W are accommodated. The cooling unit CR shown in FIG. 6 includes a first cooling layer CRA and a second cooling layer CRB. The heating unit HT shown in FIG. 6 includes a first heating layer HTA and a second heating layer HTB. The gas supply port unit MU shown in FIG. 6 includes a first gas supply port MUA and a second gas supply port MUB.

In the configuration shown in FIG. 6, the second wall 1b (the second heat insulating layer 1b1) is disposed above the second end surface 2b1 of the magnet unit 2; the second cooling layer CRB is disposed above the second wall 1b; the second heating layer HTB is disposed above the second cooling layer CRB; the wafer W supported by the support unit PP is disposed above the second heating layer HTB; the first heating layer HTA is disposed above the wafer W; the first cooling layer CRA is disposed above the first heating layer HTA; the first wall 1a (the first heat insulating layer 1a1) is disposed above the first cooling layer CRA; and the first end surface 2a1 of the magnet unit 2 is disposed above the first wall 1a. The gas supply port unit MU is disposed in the processing chamber 1 shown in FIG. 6.

In the processing chamber 1 shown in FIG. 6, the first cooling layer CRA is disposed between the first end surface 2a1 of the magnet unit 2 and the position PT (arrangement position) of the wafer W in the processing chamber 1 in a state where the wafer W is supported by the support unit PP. In the processing chamber 1 shown in FIG. 6, the second cooling layer CRB is disposed between the position PT and the second end surface 2b1 of the magnet unit 2 in the processing chamber 1.

In the processing chamber 1 shown in FIG. 6, the first heating layer HTA is an infrared heater or a lamp heater. In the processing chamber 1 shown in FIG. 6, the first heating layer HTA is disposed between the position PT and the first cooling layer CRA. In the processing chamber 1 shown in FIG. 6, the second heating layer HTB is an infrared heater or a lamp heater. In the processing chamber 1 shown in FIG. 6, the second heating layer HTB is disposed between the position PT and the second cooling layer CRB.

In the processing chamber 1 shown in FIG. 6, the first cooling layer CRA is disposed between the first wall 1a and the first heating layer HTA. The first cooling layer CRA may be in contact with the first wall 1a and the first heating layer HTA. In the processing chamber 1 shown in FIG. 6, the second cooling layer CRB is disposed between the second wall 1b and the second heating layer HTB. The second cooling layer CRB may be in contact with the second wall 1b and the second heating layer HTB. In the processing chamber 1 shown in FIG. 6, the position PT is spaced apart from the first heating layer HTA and the second heating layer HTB.

In the processing chamber 1 shown in FIG. 6, the cooling gas supplied from the gas supply device GS is injected from the first cooling layer CRA into the processing space Sp through the first gas supply port MUA, and also injected from the second cooling layer CRB into the processing space Sp through the second gas supply port MUB.

In the configuration shown in FIG. 6, the heating and the cooling are performed on each of two different surfaces of the wafer W. Therefore, the wafer W can be sufficiently heated and cooled within a shorter period of time. Further, in the case of sequentially heating and cooling the wafer W, the heated wafer W can be more effectively cooled.

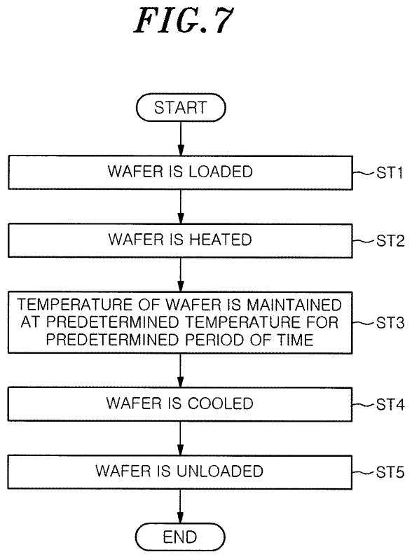

Hereinafter, the processing shown in FIG. 7 will be described. In one embodiment, the wafer W may be processed by the following steps ST1 to ST5 shown in FIG. 7. First, the wafer W is loaded into the processing chamber 1 through the gate valve RA and placed at the position PT (see FIGS. 4 to 6) in the processing chamber 1 (step ST1).

In step ST2 subsequent to step ST1, the wafer W is heated to a predetermined temperature by the heating unit HT. When the heating unit HT is the resistance heater shown in FIG. 4, the heating unit HT performs heating constantly and starts the heating when the wafer W is mounted on the heating unit HT. When the heating unit HT is the infrared heater or the lamp heater shown in FIGS. 5 and 6, the heating unit HT is turned on after the wafer W is placed at the position PT in the processing chamber 1 and, then, the wafer W is heated by a preset power.

In step ST3 subsequent to step ST2, the temperature of the wafer W is maintained at the predetermined temperature for a predetermined period of time. In the step ST3, the temperature of the wafer W is maintained in a range from 300° C. and 500° C. for 1 sec to 10 min.

In step ST4 subsequent to step ST3, the wafer W is cooled. In step ST4, the wafer W is cooled at a cooling speed of 0.5° C./sec or higher. The cooling speed can be controlled by the flow rate of the cooling gas and the pressure in the processing chamber 1. The cooling speed increases as the flow rate of the cooling gas increases and the pressure in the processing chamber 1 becomes higher.

In the case that the heating unit HT is the resistance heater shown in FIG. 4, the wafer W may be cooled in step ST4 subsequent to step ST3 while being spaced apart by the support pins PA from the heating stage shown in FIG. 4. Herein, the heating stage is configured to have therein the heating unit HT and mount thereon the wafer W. The same can be applied to the heating stage described below. In the case shown in FIG. 4, the heating unit HT itself may be the heating stage.

In the case that the heating unit HT is the resistance heater shown in FIG. 4, the position of the wafer W during the heating in steps ST2 and ST3 (i.e., the position of wafer W mounted on the heating stage shown in FIG. 4) is set to be lower than the position PT shown in FIG. 4. Then, after the heating of the wafer W is completed (after step ST3), the wafer W may be cooled in step ST4 while being spaced apart by the support pins PA from the heating stage. In this case, the position of the wafer W in step ST4 may be the position PT shown in FIG. 4.

In the case that the heating unit HT is the infrared heater or the lamp heater shown in FIGS. 5 and 6, the cooling in step ST4 may be performed by supplying a cooling gas from the cooling unit CR after the heating unit HT is turned off.

In step ST5 subsequent to step ST4, the wafer W is unloaded from the processing chamber 1 through the gate valve RA. The unloading of the wafer W in step ST5 can be started when the temperature of the wafer W becomes lower than or equal to a temperature at which the wafer W can be unloaded. The time period required to cool the wafer W in step ST5 may be previously measured and determined.

While certain embodiments have been described, these embodiments have been presented by way of example only, and are not intended to limit the scope of the invention. Indeed, the embodiments described herein may be embodied in a variety of other forms. Furthermore, various omissions, substitutions and changes in the form of the embodiments described herein may be made departing from the spirit of the invention. The accompanying claims and their equivalents are intended to cover such forms or modifications as would fall within the scope and spirit of the invention.

### EXPLANATION OF REFERENCE NUMERALS

1: processing chamber
10: substrate processing device
100: processing system,
100a: processing chamber
121: transfer chamber
122a-122d: stage,
124a-122d: container
1a: first wall,
1a1: first heat insulating layer
1b: second wall,
1b1: second heat insulating layer
1c: gas exhaust line
2: magnet unit
2a: first core portion,
2a1: first end surface
2b: second core portion,
2b1: second end surface
3a, 3b: wire portion
4: yoke
Cnt: controller,
CR: cooling unit
CRA: first cooling layer,
CRB: second cooling layer
DR, EF, ES: power supply
GA1, GA2, GB1, GB2: gate
GS: gas supply unit
HT: heating unit,
HTA: first heating layer,
HTB: second heating layer
JD1: support table,
JD2: support column
LL1, LL2: load-lock chamber
LM: loader module
MU: gas supply port unit
MUA: first gas supply port,
MUB: second gas supply port
MV: moving mechanism
OC: characteristic value measuring device
OM: opening,
OMP: notch
PA: support pins,
PP: support table
PT: position,
RA: gate valve
Rb1, Rb2: transfer robot
Sp: processing space,
TU: chiller unit,
W: wafer

1. A substrate processing device for processing substrates one by one, each having a magnetic layer, the substrate processing device comprising:
a support unit configured to supporting a substrate;
a heating unit configured to heat the substrate supported by the support unit;
a cooling unit configured to cool the substrate supported by the support unit;
a processing chamber configured to accommodate the support unit, the heating unit, and the cooling unit; and
a magnet unit configured to generate a magnetic field,
wherein the magnet unit has a first end surface and a second end surface extending in parallel to each other,
the first end surface and the second end surface are opposite to each other while being spaced apart from each other,
the first end surface corresponds to a first magnetic pole of the magnet unit, the second end surface corresponds to a second magnetic pole of the magnet unit, and
the processing chamber is disposed between the first end surface and the second end surface.

2. The substrate processing device of claim 1, wherein in a state where the substrate is supported by the support unit, the substrate is disposed to be covered by the first end surface when viewed from the first end surface and by the second end surface when viewed from the second end surface while the substrate extends in parallel with the first end surface and the second end surface.

3. The substrate processing device of claim 1, wherein in a state where the substrate is supported by the support unit in the processing chamber, the cooling unit is disposed between a position of the substrate in the processing chamber and the first end surface, and the heating unit is disposed between the position of the substrate and the second end surface.

4. The substrate processing device of claim 3, further comprising:
a moving mechanism configured to move the substrate,
wherein in the state where the substrate is supported by the support unit, the moving mechanism moves the substrate toward or away from the cooling unit while maintaining the substrate in parallel with the first end surface and the second end surface.

5. The substrate processing device of claim 1, wherein in a state where the substrate is supported by the support unit in the processing chamber, the cooling unit is disposed between a position of the substrate in the processing chamber and the first end surface, and the heating unit is disposed between the position of the substrate and the cooling unit.

6. The substrate processing device of claim 1, wherein the heating unit includes a first heating layer and a second heating layer, and
the cooling unit includes a first cooling layer and a second cooling layer,
wherein in a state where the substrate is supported by the support unit in the processing chamber, the first cooling layer is disposed between a position of the substrate in the processing chamber and the first end surface,
the second cooling layer is disposed between the position of the substrate in the processing chamber and the second end surface,
the first heating layer is disposed between the position of the substrate and the first cooling layer, and
the second heating layer is disposed between the position of the substrate and the second cooling layer.

7. A processing system comprising:
a plurality of film forming apparatuses;
the substrate processing device described in claim 1; and
a measuring device,
wherein the film forming apparatuses are configured to form magnetic layers on substrates, respectively;
the substrate processing device is configured to process the substrates having the magnetic layers formed by the film forming apparatuses one by one; and
the measuring device is configured to measure electromagnetic characteristic values of the substrates having the magnetic layers formed by the film forming apparatuses and the substrates processed by the substrate processing device one by one.

8. The processing system of claim 7, further comprising:
an atmospheric transfer chamber,
wherein the measuring device is connected to the atmospheric transfer chamber.

9. The processing system of claim 7, wherein each of the electromagnetic characteristic values is a magnetoresistance ratio.

10. The substrate processing device of claim 2, wherein in the state where the substrate is supported by the support unit in the processing chamber, the cooling unit is disposed between a position of the substrate in the processing chamber and the first end surface, and
the heating unit is disposed between the position of the substrate and the second end surface.

11. The substrate processing device of claim 10, further comprising:
a moving mechanism configured to move the substrate,
wherein in the state where the substrate is supported by the support unit, the moving mechanism moves the substrate toward or away from the cooling unit while maintaining the substrate in parallel with the first end surface and the second end surface.

12. The substrate processing device of claim 2, wherein in the state where the substrate is supported by the support unit in the processing chamber, the cooling unit is disposed between a position of the substrate in the processing chamber and the first end surface, and
the heating unit is disposed between the position of the substrate and the cooling unit.

13. The substrate processing device of claim 2, wherein the heating unit includes a first heating layer and a second heating layer, and
the cooling unit includes a first cooling layer and a second cooling layer,
wherein in the state where the substrate is supported by the support unit in the processing chamber, the first cooling layer is disposed between a position of the substrate in the processing chamber and the first end surface,
the second cooling layer is disposed between the position of the substrate in the processing chamber and the second end surface,
the first heating layer is disposed between the position of the substrate and the first cooling layer, and
the second heating layer is disposed between the position of the substrate and the second cooling layer.

14. A processing system comprising:
a plurality of film forming apparatuses;
the substrate processing device described in claim 2; and
a measuring device,
wherein the film forming apparatuses are configured to form magnetic layers on substrates, respectively;
the substrate processing device is configured to process the substrates having the magnetic layers formed by the film forming apparatuses one by one; and
the measuring device is configured to measure electromagnetic characteristic values of the substrates having the magnetic layers formed by the film forming apparatuses and the substrates processed by the substrate processing device one by one.

15. The processing system of claim 14, further comprising:
an atmospheric transfer chamber,
wherein the measuring device is connected to the atmospheric transfer chamber.

16. The processing system of claim 14, wherein each of the electromagnetic characteristic values is a magnetoresistance ratio.

17. The processing system of claim 8, wherein each of the electromagnetic characteristic values is a magnetoresistance ratio.

18. The processing system of claim 15, wherein each of the electromagnetic characteristic values is a magnetoresistance ratio.
